(19) United States
(12) Patent Application Publication
(10) Pub. No.: US 2025/0311512 A1
(43) Pub. Date: Oct. 2, 2025

(54) LIGHTING-BOARD PACKAGING STRUCTURE

(71) Applicant: QISDA CORPORATION, Taoyuan City (TW)

(72) Inventors: Bing-Hann Leu, Taoyuan City (TW); Ching-Tze Huang, Taoyuan City (TW); Kuo-Chun Lee, Taoyuan City (TW); Cheng-Chieh Juan, New Taipei City (TW)

(73) Assignee: QISDA CORPORATION, Taoyuan City (TW)

(21) Appl. No.: 19/017,811

(22) Filed: Jan. 13, 2025

(30) Foreign Application Priority Data
Mar. 29, 2024 (CN) 202410373315.4

(51) Int. Cl. H10H 29/854; H10H 29/80; H10H 29/855

(52) U.S. Cl. CPC H10H 29/854; H10H 29/842; H10H 29/8552; H10H 29/882

(57) ABSTRACT

A lighting-board packaging structure includes a circuit substrate, an LED chip, a diffuser structure, a black light-transmissive layer, a haze layer, and an anti-reflection layer. The LED chip is disposed on the circuit substrate by a chip-on-board process and emits a color light. The diffuser structure has two types of scattering particles doped therein and covers the LED chip for homogenizing and diffusing the color light. A doping concentration of each of the two types of scattering particles in the diffuser structure is not greater than 10%. The black light-transmitting layer is stacked on the diffuser structure to reduce reflection of an ambient light incident to the lighting-board packaging structure. The haze layer is stacked on the black light-transmissive layer for scattering the ambient light. The anti-reflection layer is stacked on the haze layer for allowing the ambient light to enter.

### BACKGROUND OF THE INVENTION

### 1. Field of the Invention

The present invention relates to a lighting-board packaging structure, and more specifically, to a lighting-board packaging structure that adopts a chip-on-board process, incorporates at least two types of scattering particles with doping concentrations of no more than 10% into a diffuser structure, and has an anti-reflection layer, a haze layer, a black light-transmissive layer, and a diffuser structure stacked sequentially from top to bottom.

### 2. Description of the Prior Art

With the rapid development of LED packaging technology, the design of packaging multiple LEDs on a single circuit board to serve as a light source board has been widely applied in various display screen products. For example, a COB (Chip On Board) packaging design involves directly adhering all LED chips to a circuit substrate, welding wires of the LED chips to solder pads on the circuit substrate, and utilizing a transparent adhesive to cover the LED chips and the wires, thereby eliminating the manufacturing cost caused by individually packaging each LED on the circuit substrate in the prior art.

However, in this design, since each LED chip is directly adhered to the circuit substrate rather than independently packaged via a traditional SMT (Surface Mounting Technology) process, it becomes challenging to precisely control the size tolerance of the LED chips on the circuit substrate, the solder paste tolerance, and the chip alignment tolerance. As a result, the aforesaid problem often leads to optical issues, such as dark spots, bright spots, uneven brightness, and color inconsistency, which significantly affect the image display quality of the display screen products.

### SUMMARY OF THE INVENTION

The present invention provides a lighting-board packaging structure including a circuit substrate, at least one LED chip, a diffuser structure, a black light-transmissive layer, a haze layer, and an anti-reflection layer. The at least one LED chip is disposed on the circuit substrate via a chip-on-board process and emits at least one color light. The diffuser structure is doped with at least two types of scattering particles and covers the at least one LED chip for homogenizing and diffusing the at least one color light. A doping concentration of each of the two types of scattering particles in the diffuser structure is not greater than 10%. The black light-transmissive layer is stacked on the diffuser structure to reduce reflection of an ambient light incident to the lighting-board packaging structure. The haze layer is stacked on the black light-transmissive layer for scattering the ambient light. The anti-reflection layer is stacked on the haze layer to allow the ambient light to enter.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional diagram of a lighting-board packaging structure according to an embodiment of the present invention.

FIG. 2 is a cross-sectional diagram of a lighting-board packaging structure according to another embodiment of the present invention.

FIG. 3 is a cross-sectional diagram of a lighting-board packaging structure according to another embodiment of the present invention.

### DETAILED DESCRIPTION

The present invention will now be described more specifically with reference to the following embodiments and the accompanying drawings. Other advantages and effects of the present invention can be easily understood by a person ordinarily skilled in the art in view of the detailed descriptions and the accompanying drawings. The present invention can be implemented or applied to other different embodiments. Certain aspects of the present invention are not limited by the particular details of the examples illustrated herein. Without departing from the spirit and scope of the present invention, the present invention will have other modifications and changes. It should be understood that the appended drawings are not necessarily drawn to the scale and configuration of each component (e.g., sizes of packaging layers, number of LED chips on a circuit substrate, etc.) in the drawings is merely illustrative, not presenting an actual condition of the embodiments.

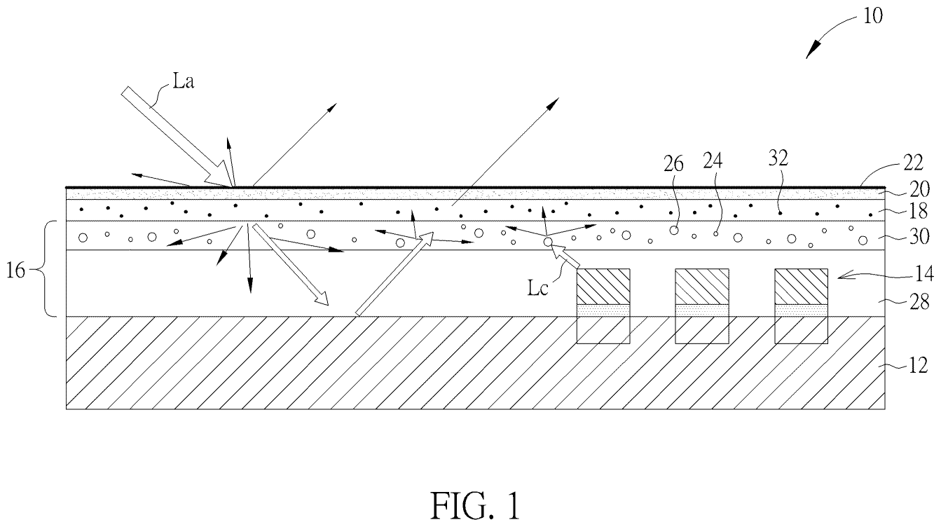

Please refer to FIG. 1, which is a cross-sectional diagram of a lighting-board packaging structure 10 according to an embodiment of the present invention. The lighting-board packaging structure 10 is preferably applied in electronic products with light source boards (e.g., liquid crystal display screens) to provide necessary color light for image display of the electronic products. As shown in FIG. 1, the lighting-board packaging structure 10 includes a circuit substrate 12, at least one LED chip 14 (three shown in FIG. 1, but not limited thereto, meaning the type and number of LED chips could be determined based on the actual application needs of the lighting-board packaging structure 10), a diffuser structure 16, a black light-transmissive layer 18, a haze layer 20, and an anti-reflection layer 22. The LED chip 14 is disposed on the circuit substrate 12 via a chip-on-board process and emits a color light Lc. For example, red, blue, and green LED chips could be configured to provide red, blue, and green light needed for image display (but not limited thereto). As for the related description for the circuit control and wiring layout between the circuit substrate 12 and the LED chip 14 and bonding/welding of the chip-on-board process, it is commonly seen in the prior art and omitted herein.

More detailed description for the packaging layer design of the lighting-board packaging structure 10 is provided as follows. As shown in FIG. 1, the diffuser structure 16 is doped with at least two types of scattering particles and covers the LED chip 14 to scatter the color light Lc emitted by the LED chip 14, so as to generate a color light homogenization and diffusion effect and improve a light output rate of the LED chip 14. Furthermore, in this embodiment, the diffuser structure 16 is preferably doped with a plurality of first scattering particles 24 and a plurality of second scattering particles 26 (material of the first scattering particle 24 and the second scattering particle 26 could preferably be selected from a group at least consisting of silicon dioxide, titanium dioxide, acrylic, aluminum oxide, and combinations thereof), but the present invention is not limited thereto, meaning the present invention could also adopt three or more types of scattering particles. For example, three types of scattering particles could be doped to correspond to red, blue, and green LED chips for enhancing the red, blue, and green light homogenization and diffusion effect. The related description could be reasoned by analogy according to the following description for FIG. 1 and omitted herein. To be noted, for effectively avoiding uneven mixing of the scattering particles with an adhesive layer or an oversaturated particle concentration leading to particle precipitation at the bottom of the adhesive layer, a doping concentration of the plurality of first scattering particles 24 and a doping concentration of the plurality of second scattering particles 26 in the diffuser structure 16 could not exceed 10%. For example (but not limited thereto), in practical applications, the plurality of first scattering particles 24 could be made of silicon dioxide material with a doping concentration in the diffuser structure 16 ranging from 6% to 9%, and the plurality of second scattering particles 26 could be made of aluminum oxide material with a doping concentration in the diffuser structure 16 ranging from 2% to 4%, thereby making a haze of the diffuser structure 16 range from 80% to 99%. In such a manner, the color light homogenization and diffusion effect of the diffuser structure 16 can be effectively enhanced.

In this embodiment, the diffuser structure 16 could include a white glue light-transmitting layer 28 and a diffusion haze layer 30. The white glue light-transmitting layer 28 could be formed by curing a high-transmittance adhesive to cover the LED chip 14. The diffusion haze layer 30 could be made of high-transmittance material, stacked on the white glue light-transmitting layer 28, and doped with the plurality of first scattering particles 24 and the plurality of second scattering particles 26. A thickness of the diffusion haze layer 30 and a thickness of the black light-transmissive layer 18 could both be less than a thickness of the white glue light-transmitting layer 28, and a refractive index of the white glue light-transmitting layer 28 could not be lower than a refractive index of the black light-transmissive layer 18 and a refractive index of the diffusion haze layer 30, thereby enhancing a light output rate of the LED chip 14 and generating a gradient refractive index effect via the packaging layer design of the lighting-board packaging structure 10. To be more specific, in this embodiment, the thickness of the white glue light-transmitting layer 28 could preferably range from 90 μm to 120 μm, and the refractive index of the white glue light-transmitting layer 28 could preferably range from 1.5 to 1.7. The thickness of the diffusion haze layer 30 could preferably range from 30 μm to 40 μm, and the refractive index of the diffusion haze layer 30 could preferably range from 1.45 to 1.55. The thickness of the black light-transmissive layer 18 could preferably range from 30 μm to 50 μm, and the refractive index of the black light-transmissive layer 18 could preferably range from 1.4 to 1.55.

In addition, the black light-transmissive layer 18 could be made of high-transmittance material and stacked on the diffuser structure 16, and the black light-transmissive layer 18 could be doped with a plurality of light-absorbing particles 32, thereby making a transmittance of the black light-transmissive layer 18 range from 70% to 85% to reduce reflection of an ambient light La incident on the lighting-board packaging structure 10. Material of the light-absorbing particles 32 could preferably be selected from a group at least consisting of iron oxide, carbon black, and combinations thereof. Via the aforesaid configuration of the black light-transmissive layer 18, during the process of the ambient light La entering and then reflecting in the lighting-board packaging structure 10, the ambient light La passes through the black light-transmissive layer 18 twice. In such a manner, the black light-transmissive layer 18 can significantly reduce and absorb brightness of the ambient light La and homogenize the ambient light La diffused and reflected by the diffusion haze layer 30, thereby enhancing the black consistency that the lighting-board packaging structure 10 can present.

Furthermore, the haze layer 20 is stacked on the black light-transmissive layer 18 to scatter the ambient light La incident on the lighting-board packaging structure 10, and the anti-reflection layer 22 is stacked on the haze layer 20 to allow the ambient light La to enter the haze layer 20. This effectively increases a transmittance of the lighting-board packaging structure 10 and reduces the distinctness of image (DOI) of reflection of the ambient light La, so as to achieve a matte effect. In this embodiment, the haze layer 20 could be made of an anti-glare (AG) coating layer with a rough surface, with a thickness preferably ranging from 50 μm to 100 μm, a haze ranging from 30% to 50%, and a reflectance not greater than 1.5%. The anti-reflection layer 22 is preferably selected from a group at least consisting of an anti-reflection (AR) film layer, a low reflection (LR) film layer, and combinations thereof.

In summary, via the packaging layer design that sequentially stacks the anti-reflection layer, the haze layer, the black light-transmissive layer, and the diffuser structure from top to bottom, where the diffuser structure is doped with at least two types of scattering particles with doping concentrations not exceeding 10%, the present invention can homogenize and diffuse a color light pattern of the LED chip mounted on the circuit substrate by the chip-on-board process. As such, the present invention can effectively improves the optical issues in the prior art, such as dark spots, bright spots, uneven brightness, and color inconsistency, so as to enhance the image display quality of the display screen products.

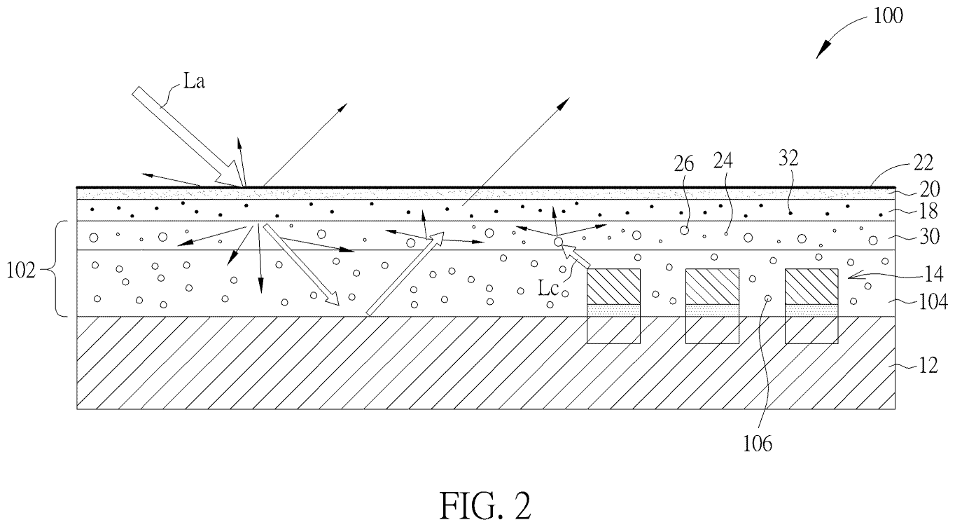

It should be mentioned that the scattering particle doping configuration used in the present invention is not limited to the aforementioned embodiment. For example, please refer to FIG. 2, which is a cross-sectional diagram of a lighting-board packaging structure 100 according to another embodiment of the present invention. Components both mentioned in this embodiment and the aforesaid embodiments represent components with similar structures or functions, and the related description is omitted herein. As shown in FIG. 2, the lighting-board packaging structure 100 includes the circuit substrate 12, at least one LED chip 14 (three are shown in FIG. 2, but not limited thereto, meaning the type and number of LED chips could be determined based on the actual application needs of the lighting-board packaging structure 100), a diffuser structure 102, the black light-transmissive layer 18, the haze layer 20, and the anti-reflection layer 22. In this embodiment, the diffuser structure 102 could include a white glue light-transmitting layer 104 and the diffusion haze layer 30. The white glue light-transmitting layer 104 could be formed by curing a high-transmittance adhesive to cover the LED chip 14 and doped with a plurality of third scattering particles 106. Material of the third scattering particle 106 could preferably be selected from a group at least consisting of silicon dioxide, titanium dioxide, acrylic, aluminum oxide, and combinations thereof, with a doping concentration in the white glue light-transmitting layer 104 ranging from 3% to 11%. In such a manner, via the packaging layer design that incorporates the three types of scattering particles with the doping concentrations not exceeding 10% into the diffuser structure, the present invention can homogenize and diffuse the color light pattern of the LED chip mounted on the circuit substrate by a chip-on-board process. Thus, the present invention can solve the optical issues in the prior art, such as dark spots, bright spots, uneven brightness, and color inconsistency, thereby enhancing the image display quality of display screen products. The related description for other designs of the lighting-board packaging structure 100 (e.g., the thickness/refractive-index design of the white glue light-transmitting layer, etc.) could be reasoned by analogy according to the aforementioned embodiments and omitted herein.

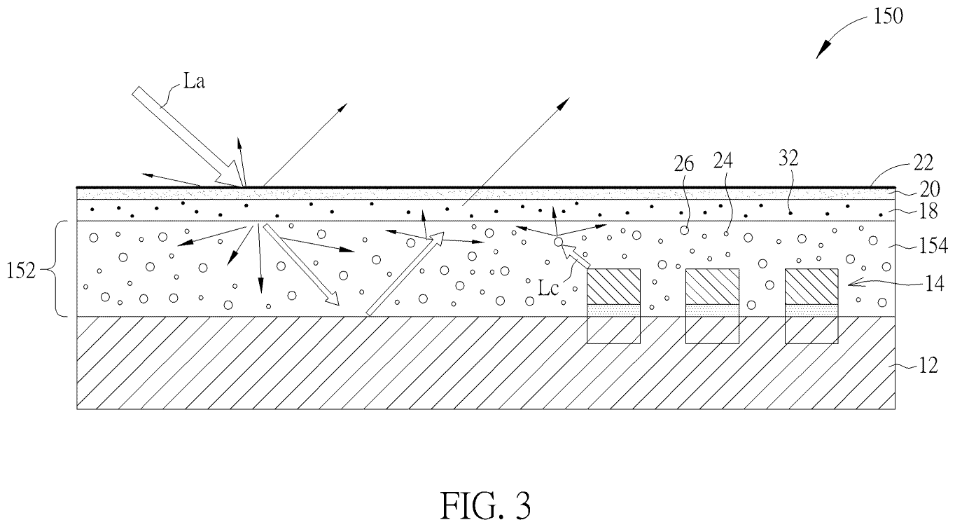

In addition, in practical applications, the present invention could omit the white glue light-transmitting layer to simplify the packaging layer design of the lighting-board packaging structure. To be brief, please refer to FIG. 3, which is a cross-sectional diagram of a lighting-board packaging structure 150 according to another embodiment of the present invention. Components both mentioned in this embodiment and the aforesaid embodiments represent components with similar structures or functions, and the related description is omitted herein. As shown in FIG. 3, the lighting-board packaging structure 150 includes the circuit substrate 12, at least one LED chip 14 (three are shown in FIG. 3, but not limited thereto, meaning the type and number of LED chips could be determined based on the actual application needs of the lighting-board packaging structure 150), a diffuser structure 152, the black light-transmissive layer 18, the haze layer 20, and the anti-reflection layer 22. In this embodiment, the diffuser structure 152 could only include a diffusion haze layer 154. The diffusion haze layer 154 could be made of high-transmittance material to cover the LED chip 14 and doped with the plurality of first scattering particles 24 and the plurality of second scattering particles 26. The thickness of the black light-transmissive layer 18 is less than a thickness of the diffusion haze layer 154, and a refractive index of the diffusion haze layer 154 could not be lower than the refractive index of the black light-transmissive layer 18, thereby enhancing the light output rate of the LED chip 14 and generating a gradient refractive index effect via the packaging layer design of the lighting-board packaging structure 150. For example, in this embodiment, the thickness of the diffusion haze layer 154 could range from 120 μm to 160 μm, and the refractive index of the diffusion haze layer 154 could range from 1.45 to 1.55. As such, the present invention can homogenize and diffuse the color light pattern of the LED chip mounted on the circuit substrate by a chip-on-board process. Thus, the present invention can solve the optical issues in the prior art, such as dark spots, bright spots, uneven brightness, and color inconsistency, thereby enhancing the image display quality of display screen products.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A lighting-board packaging structure comprising:
a circuit substrate;
at least one LED chip disposed on the circuit substrate via a chip-on-board process and emitting at least one color light;
a diffuser structure doped with at least two types of scattering particles and covering the at least one LED chip for homogenizing and diffusing the at least one color light, a doping concentration of each of the two types of scattering particles in the diffuser structure being not greater than 10%;
a black light-transmissive layer stacked on the diffuser structure to reduce reflection of an ambient light incident to the lighting-board packaging structure;
a haze layer stacked on the black light-transmissive layer for scattering the ambient light; and
an anti-reflection layer stacked on the haze layer to allow the ambient light to enter.

2. The lighting-board packaging structure of claim 1, wherein the diffuser structure comprises:
a white glue light-transmitting layer covering the at least one LED chip; and
a diffusion haze layer stacked on the white glue light-transmitting layer and doped with the at least two types of scattering particles.

3. The lighting-board packaging structure of claim 2, wherein a thickness of the diffusion haze layer and a thickness of the black light-transmissive layer are both less than a thickness of the white glue light-transmitting layer.

4. The lighting-board packaging structure of claim 3, wherein the thickness of the white glue light-transmitting layer ranges from 90 μm to 120 μm, the thickness of the diffusion haze layer ranges from 30 μm to 40 μm, and the thickness of the black light-transmissive layer ranges from 30 μm to 50 μm.

5. The lighting-board packaging structure of claim 2, wherein a refractive index of the white glue light-transmitting layer is not less than a refractive index of the black light-transmissive layer and a refractive index of the diffusion haze layer.

6. The lighting-board packaging structure of claim 5, wherein the refractive index of the white glue light-transmitting layer ranges from 1.5 to 1.7, the refractive index of the diffusion haze layer ranges from 1.45 to 1.55, and the refractive index of the black light-transmissive layer ranges from 1.4 to 1.55.

7. The lighting-board packaging structure of claim 2, wherein the at least two types of scattering particles comprises a plurality of first scattering particles and a plurality of second scattering particles, and material of the first scattering particle and the second scattering particle is selected from a group at least consisting of silicon dioxide, titanium dioxide, acrylic, aluminum oxide, and combinations thereof.

8. The lighting-board packaging structure of claim 7, wherein the plurality of first scattering particles and the plurality of second scattering particles are doped into the diffusion haze layer; the first scattering particle is made of silicon dioxide material, and the second scattering particle is made of aluminum oxide material; a doping concentration of the plurality of first scattering particles in the diffusion haze layer ranges from 6% to 9%, and a doping concentration of the plurality of second scattering particles in the diffusion haze layer ranges from 2% to 4%, resulting in a haze of the diffusion haze layer ranging from 80% to 99%.

9. The lighting-board packaging structure of claim 7, wherein the at least two types of scattering particles further comprises a plurality of third scattering particles, the plurality of third scattering particles is doped into the white glue light-transmitting layer, material of the third scattering particle is selected from a group at least consisting of silicon dioxide, titanium dioxide, acrylic, aluminum oxide, and combinations thereof, and a doping concentration of the plurality of third scattering particles in the white glue light-transmitting layer ranges from 3% to 11%.

10. The lighting-board packaging structure of claim 1, wherein the black light-transmissive layer is doped with a plurality of light-absorbing particles, resulting in a transmittance of the black light-transmissive layer ranging from 70% to 85%.

11. The lighting-board packaging structure of claim 10, wherein material of the light-absorbing particle is selected from a group at least consisting of iron oxide, toner, and combinations thereof.

12. The lighting-board packaging structure of claim 1, wherein a thickness of the haze layer ranges from 50 μm to 100 μm, a haze of the haze layer ranges from 30% to 50%, and a reflectance of the haze layer is not greater than 1.5%.

13. The lighting-board packaging structure of claim 12, wherein the haze layer is made of an anti-glare (AG) coating layer a rough surface.

14. The lighting-board packaging structure of claim 1, wherein the anti-reflection layer is selected from a group at least consisting of an anti-reflection (AR) film layer, a low reflection (LR) film layer, and combinations thereof.
